(19) United States
(12) Patent Application Publication
(10) Pub. No.: US 2015/0187729 A1
(43) Pub. Date: Jul. 2, 2015

(54) Wire Stitch Bond Having Strengthened Heel

(71) Applicant: Texas Instruments Incorporated, Dallas, TX (US)

(72) Inventor: Jiun Wai Chew, Perak (MY)

(21) Appl. No.: 14/146,283

(22) Filed: Jan. 2, 2014

(51) Int. Cl. H01L 23/00

(52) U.S. Cl. CPC H01L 24/85; H01L 24/78; H01L 24/49; H01L 2224/85205; H01L 2224/85345

(57) ABSTRACT

A semiconductor chip (1100) assembled on a substrate (1110), the chip having bond pads (1102) and the substrate having contact pads (1111). Wires (1101) form arches to connect electrically the chip and the substrate, the wires forming first bonds (1103, e.g. ball bonds) on the chip bond pads and second bonds (1107, e.g. stitch bonds) on the substrate contact pads. The second (stitch) bonds have bendings (heels) 1106 with metal bulges (1106a) near the vertex of the bending.

### FIELD OF THE INVENTION

The present invention is related in general to the field of semiconductor devices and processes, and more specifically to the structure of wire stitch bonds and the process and tools of fabricating reliable stitch bonds.

### DESCRIPTION OF RELATED ART

In semiconductor industry, traditionally the most widely used technology for electrically interconnecting chip terminals to external pads is wire bonding, especially ball bonding, as indicated in FIG. 1. Typically, the wires 111, made of gold, copper, or aluminum, have diameters between about 15 and 33 μm. A routine wire bonding process may begin with positioning the semiconductor chip on a heated pedestal to raise the temperature to between 150 and 300° C. For copper and aluminum wires, ball formation and bonding may need to be performed in a reducing atmosphere such as dry nitrogen gas with a few percent hydrogen gas. The wire is strung through the capillary of an automated bonder. A capillary is an elongated tube of an inert material such as a ceramic with a fine bore (the capillary in the strict sense) suitable for guiding a metal wire in the 15 to 33 μm diameter range. At the wire end extruding from the capillary tip, a free air ball is created by melting the wire end using either a flame or a spark technique. The ball has a typical diameter from about 1.2 to 1.6 wire diameters. The capillary is moved towards an attachment pad 102, usually an alloy of aluminum and copper. The ball is pressed against the metallization of the pad by a combination of compression force and ultrasonic movement of the ball relative to the pad, transmitting ultrasonic energy. The attachment process progressively forms metal interdiffusions and intermetallics of a thickness between about 50 and 100 nm. The compression (also called Z- or mash) force is typically between about 17 and 75 gram-force/cm² (about 1670 to 7355 Pa); the ultrasonic time between about 10 and 30 ms; the ultrasonic power between about 20 and 50 mW. The bonding process results in a metal nail head or squashed ball 103.

After the ball attachment, the capillary with the wire is lifted to span an arch 104 from the ball 103 to a pad 105 on a substrate or a leadframe. When the wire touches the pad surface, the capillary tip is pressed against the wire in order to flatten it and thus to form a stitch bond 106, sometimes referred to as a wedge bond. For substrate-based pads, the bonding temperature is typically about 160° C.; for leadframe-based pads, the bonding temperature may be between 240 and 260° C. The bonding force is typically in the range from about 50 to 150 gram-force, and the ultrasonic energy in the range from about 80 to 180 mA. Based on the geometric shape of the capillary tip, the capillary leaves an imprint 107 in the flattened portion of the attached wire. The wire portion 106 with the transition from the round wire to the flattened wire is bent and is called the heel of the stitch bond; the binding has a vertex 106a.

The capillary rises again to a height sufficient to display a length of wire with enough metal to form the next ball. Then, a tear method is initiated to break the wire near the end of the stitch bond and leave the exposed wire length dangling from the capillary tip ready for the next ball-forming melting step. Various wire-breaking methods are commonly employed, among them the so-called clamp-tear method and the table-tear method.

Standardized bond pull tests, with pulls measured in gram-force, are used to gauge the strength of the stitch bonds. The pull tests to measure the quality of the bonds may be repeated by pull tests to measure the reliability after any of the numerous standardized accelerated life tests, moisture tests, and electrical stress tests.

### SUMMARY OF THE INVENTION

Analyzing large numbers of wire stitch bonds which failed in bond pull tests of quality and reliability investigations of wire-bonded semiconductor devices, applicant found that the majority of the failures showed as symptom wires broken at the heel of the stitch bonds. The heel is the portion of the wire where the wire tapers off into the wedge bond, or crescent bond. The bond heel turned out to be the weakest region of the bonded wire.

Detailed failure analysis identified as a root causes of the breakage the propagation of bond delamination to the bond heel until the bond heel as the weakest point develops microcracks and is breaking, and furthermore the stress at the bond heel due to wire looping and wire imprint formation. In addition, there is thermo-mechanical stress caused by the mismatch of the coefficients of thermal expansion (CTE) between the metal of the wire, the material of the pad, and the polymeric compound of the encapsulation. In temperature cycles, this CTE mismatch exerts pulling forces on the wire bond.

Attempts to eliminate the heel breakage by changing the encapsulation compound, optimizing the machine parameters, and careful capillary maintenance had only limited success. By tweaking the CTE of the encapsulation compound, the stress caused by CTE mismatch to the wire metal can be somewhat reduced. The machine parameters such as force, power, and time of bonding, loop height, and temperature at bonding can be varied within narrow limits to reduce stress at the bond heel. Capillary maintenance may aim at controlling bond tool life to minimize the stress on bond heel due to residue build-up.

Applicant substantially solved the heel breakage problem when he discovered that additional wire metal intentionally accumulated right in the heel during the process of wire stitch formation will fortify the heel strength so much that heel breakage is prevented throughout the pull testing range. Applicant further developed a methodology to accumulate the needed additional wire metal by carving additional recesses, chamfers or grooves into the capillary tip region so that wire metal is pressed into these recesses when the wire metal is at elevated temperature, under pressure, and softened by ultrasonic energy during the bonding process. He found especially effective regions for the recesses when the capillary tip is contoured for optimizing it for certain bonding processes. The recess-enhanced capillary tip acts as a mold to shape the additional metal as a bulge or bump in the region of maximum wire bending during the bonding time period of elevated temperature, pressure and ultrasonic energy application.

An exemplary embodiment for use in wire bonders is an apparatus with a tungsten carbide tube surrounding a space shaped as a capillary for guiding metal wires of about 20 to 30 μm diameter. The tube has a tip contoured by two intersecting planes. The first plane is at right angle to the tube length and the second plane at an acute angle; the intersection is touching the mouth of the capillary. At the intersection, the tungsten carbide is forming a first curve from the first plane into the capillary mouth, and at the edge of the first plane and the tube surface, the tungsten carbide is forming a second curve. A concave recess is in the tungsten carbide material of the first and the second curves.

### BRIEF DESCRIPTION OF THE DRAWINGS

FIG. 1 illustrates a bonded wire with ball bond and stitch bond according to existing technology.

FIG. 2 is a perspective scanning electron microscope photograph (magnification 600×) of the tip of a tube with capillary bore as used in wire bonding displaying the rounded zones at certain edges.

FIG. 3A depicts a cross section through the capillary tip of FIG. 2, displaying the tip contours determined by the intersection of a first and a second plane and the edge roundings with front radius and back radius.

FIG. 3B shows a side view of the capillary tip, indicating the tapering of the capillary tip.

FIG. 4 illustrates a test structure for investigating the strengths of wire stitch bonds.

FIG. 5A is a cross section of the tube tip with a wire loaded into the capillary and a wire tail protruding from the capillary mouth.

FIG. 5B shows the step of forming and bonding the wire tail by employing the tube curving with the back radius.

FIG. 5C depicts the step of lifting the tube for spanning a wire arch.

FIG. 5D illustrates the step of forming and bonding the wire by employing the tube curving with the front radius.

FIG. 5E depicts the rising of the tube before the applying a wire tear technique.

FIG. 5F shows the wire tail after breaking the wire; the bonding cycle can begin again with FIG. 5B.

FIG. 6A is a perspective scanning electron microscope photograph (magnification 600×X) of the tip of a tube with capillary and recess in the tip contours for strengthening stitch bonds.

FIG. 6B is a further magnification of FIG. 6A illustrative the addition of a concave recess 670 into the capillary material of the first curve.

FIG. 7 illustrates the test structure of FIG. 4 including bulges created by recesses in a tube tip as shown in FIGS. 6A and 6B.

FIG. 8A is a microphotograph of a stitch bond showing the heel fortified by a metal bulge formed by the recess-enhanced front radius of the capillary tip according to the invention.

FIG. 8B is a microphotograph of a stitch bond showing the standard heel formed by the front radius of a conventional capillary tip.

FIG. 9A is a microphotograph of a stitch bond showing the heel fortified by a metal bulge formed by the recess-enhanced back radius of the capillary tip according to the invention.

FIG. 9B is a microphotograph of a stitch bond showing the standard heel formed by the back radius of a conventional capillary tip.

FIG. 10 is a diagram comparing the pull strength (in gram-force) of bonds made by a conventional capillary wedge tool and made by a recess-enhanced capillary wedge tool according to the invention.

FIG. 11 shows a perspective view of a portion of a semiconductor device with wire bonds including stitch bonds,

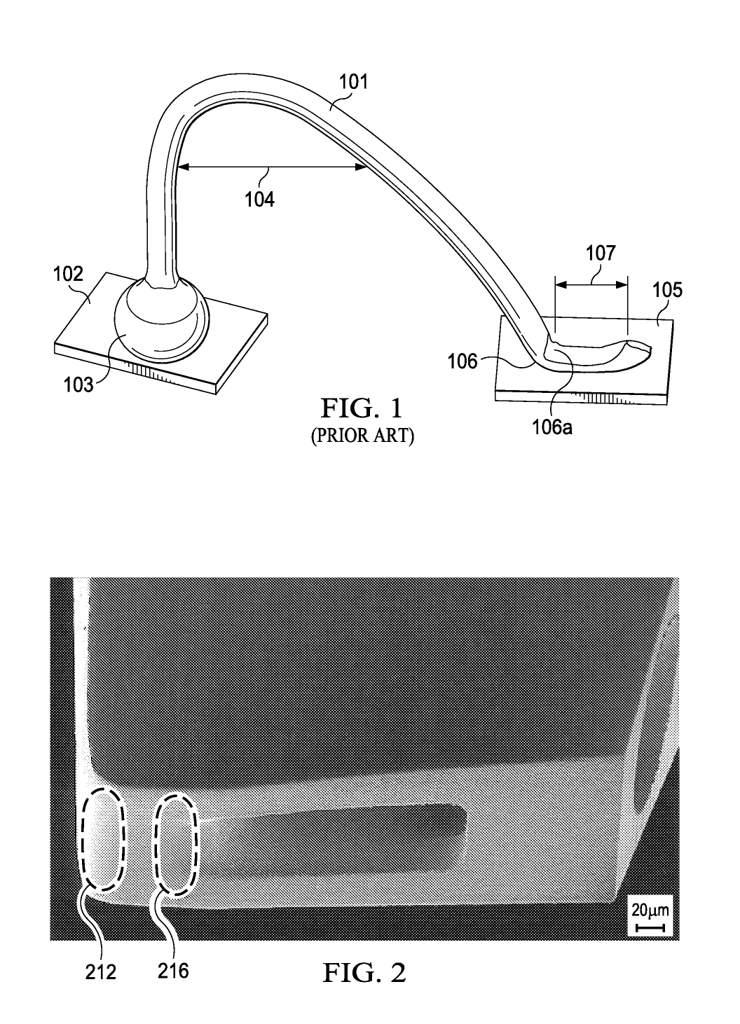

### DETAILED DESCRIPTION OF THE PREFERRED EMBODIMENTS

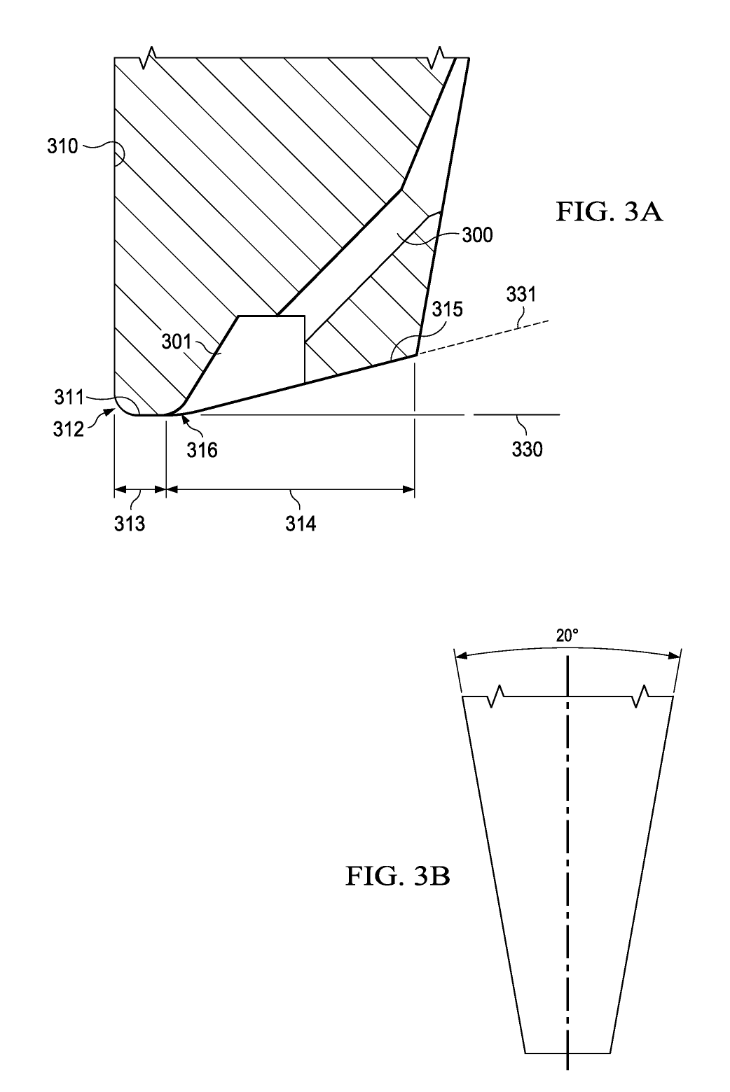

FIG. 2 illustrates a scanning electron microscope photograph (magnification 600×) of the tip, or end, of an exemplary straight tube made of an inert material such as tungsten carbide, which is preferably used in automated bonders for fabricating electrical wire connections in semiconductor devices. The tube has a certain length and inside a cylindrical bore with a very small diameter. The tube is, as a capillary tube, commonly referred to as the capillaries, or short the capillary, of wire bonders. Exemplary bores have diameters suitable to guide round metal wires with a diameter in the range from about 15 μm to 35 μm; the wires for semiconductor devices may be made of copper, gold, aluminum, or alloys of these metals. The region where the capillary bore exits the tube, is herein referred to as the capillary mouth. The perspective view of FIG. 2 shows that the mouth of the capillary bore at the tube end is elongated.

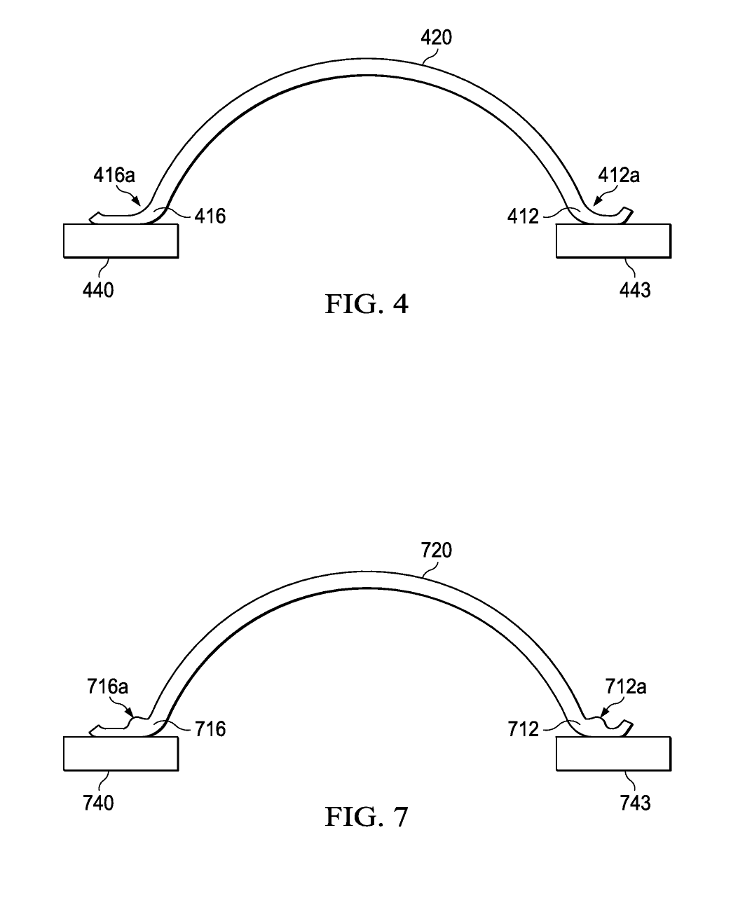

FIG. 3A is a cross section of the end portion of the capillary tube and depicts the elongated opening 301 of the bore 300 at the capillary end. The capillary tube has a straight outer surface 310, which is in the direction of the tube length. The surface 311 of the tube end is along a width 313 in a plane 330 which forms a right angle with the surface 310. The plane 330 of surface 311 is referred to as first plane. FIG. 3A indicates that the edge 312 formed by the intersecting surfaces 310 and 311 is rounded. The material at the edge of the first plane 330 and the tube surface 310 forms a first curve. The radius characterizing the first curve is called front radius 312.

The front radius determines the degree of bending, where the bonding wire tapers off into the wedge, or crescent bond, at most stitch bonds in semiconductor devices (made usually onto leadframe leads and substrate pads). Consequently, the front radius determines the bond heel at the wire bending, which has been found to be the weakest section of the bonded wire. In FIG. 2, the approximate region of the tube end, where the tube material is rounded by the front radius, is highlighted by dashed circle 212.

FIG. 3A further shows that surface 315 of the tube end, with a projected width 314, is in a plane 331, which forms acute angles with the surface 310 and with plane 330. The plane 331 is referred to as second plane. The intersection 316 of second plane 331 and first plane 330 is at the mouth of the capillary bore, which has an elongated shape at the end of the tube. FIG. 3A indicates that intersection 316 formed by the intersecting first plane 330 and second plane 331 is rounded. The material at the intersection of the first plane 330 and second plane 331 forms a second curve. The radius characterizing the second curve is called back radius 316.

The back radius determines the degree of bending, where the bonding wire tapers off into the wedge, or crescent bond, at double stitch bonds in some semiconductor devices (one stitch bond is made onto a chip bond pad, the other stitch bond onto a leadframe lead or substrate pad). Consequently, the back radius determines the bond heel at a wire bending, which has been shown to be a weak section of the bonded wire. In FIG. 2, the approximate region of the mouth of the capillary bore, where the tube material is rounded by the back radius, is highlighted by dashed circle 216.

FIG. 3B indicates that the capillary tip shown in FIG. 2 has a tapered configuration, allowing thin wall material for the capillary. Stitch bonds can be placed next to each other with only minimum spacing between them.

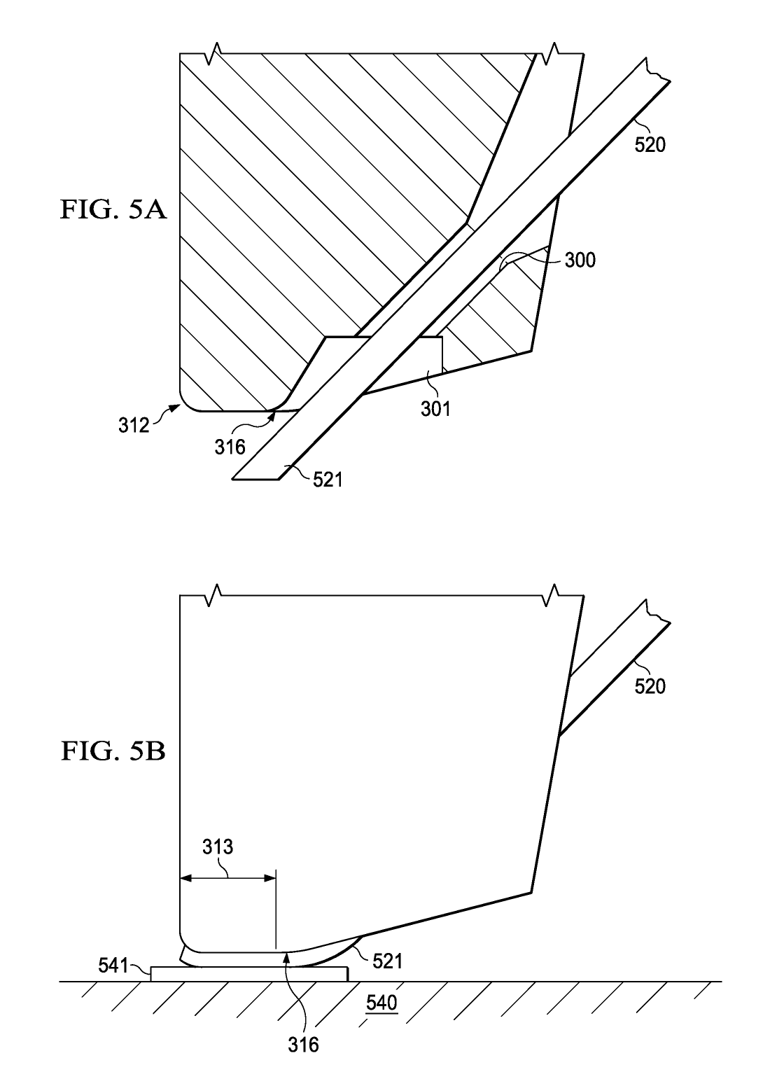

FIG. 4 shows a simple test structure to investigate strength and eventual break of stitch bonds formed from metal wire 420. The stitch bond with heel 412 has a vertex 412a influenced by the front radius of the capillary tip, and the stitch bond with heel 416 has a vertex 416a influenced by the back radius of the capillary tip. The stitch bonds may be formed under various bonding pressures, ultrasonic energies, and temperatures, and may be attached to pads (443, 440) of various metals.

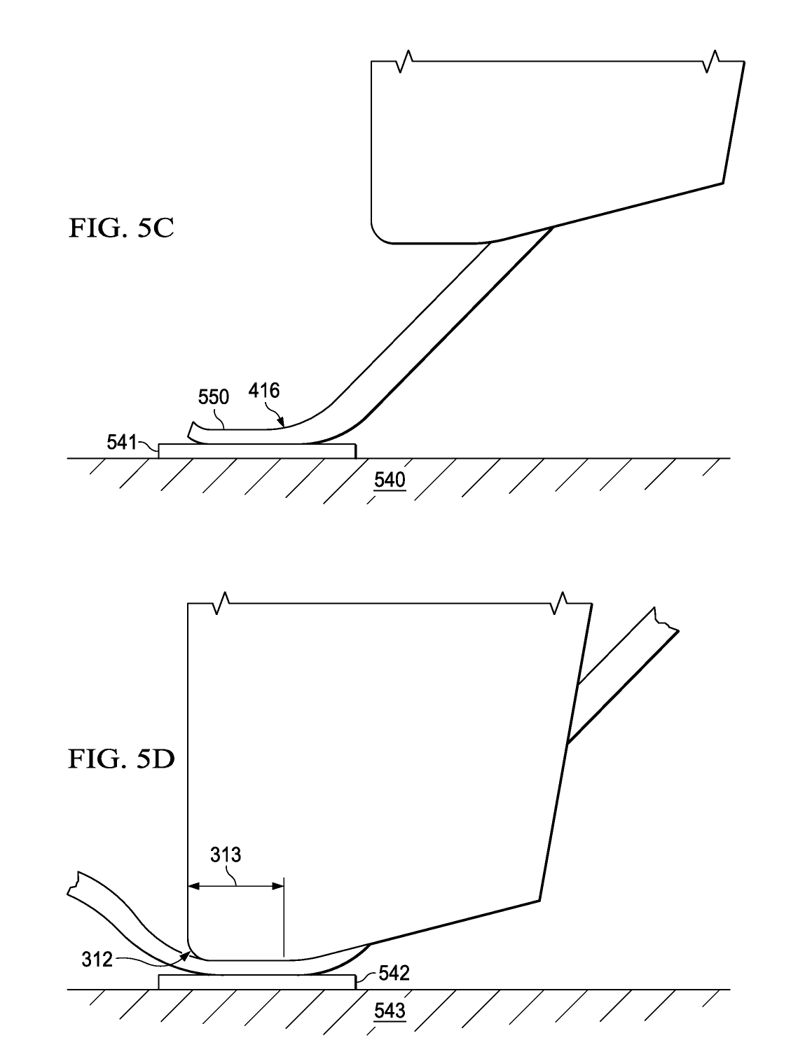

An exemplary process flow with an exemplary capillary is illustrated in FIGS. 5A to 5F, depicting certain process steps of wire stitch bonding performed by a capillary tip loaded with a bonding wire 520. The capillary tip shown in FIG. 5A is of the kind described in FIG. 3A. It is preferably made of tungsten carbide, corundum, or sapphire. In particular, it exhibits rounded edge 312, characterized by the front radius, and rounded intersection 316, characterized by the back radius. In the region 313 between the rounded regions, the capillary material is flat and in the same horizontal plane as the bonding pads (see below).

The process flow starts In FIG. 5A with the tail 521 of bonding wire 520 protruding from the elongated opening 301 of the bore 300 at the capillary end. Next, a device 540 with a first metal bond pad 541 and a substrate 543 with a second metal bond pad 542 are provided. The device and the substrate are heated to a temperature, which allows an accelerated interdiffusion of the wire metal and the bond pad metal. As an example, for a bonding wire of gold, gold alloy, or copper and the contact pad of copper or silver, a temperature between 220° C. and 250° C. is preferred.

In FIG. 5B, the tip of the capillary is moved above the first pad in order to align the protruding wire tail with the first device bond pad. The capillary is then lowered to bring the wire tail in contact with the first pad 541, bending the wire tail along the capillary curve with the back radius 316. The wire tail is clamped between the flat capillary material 313 in the horizontal plane and first pad 541, which is also in the horizontal plane. Pressure is applied to the capillary and the wire tail so that the wire is somewhat flattened. Simultaneously, ultrasonic energy is applied to the bent wire portion for a period of time to further enhance interdiffusion of the wire metal and the metal of the first pad. As a result, a stitch bond 550 is created between the wire and the first pad; the heel 416 of stitch bond 550 has been determined by the back radius 316 of the capillary.

FIG. 5C illustrates the lifting of the capillary from stitch bond 550 in order to span additional wire into a loop, which forms the arch to the next stitch bond on the second bonding pad 542. The strength of stitch bond 550 is determined by heel 416, which, in turn, is determined by back radius 316 of the capillary. In FIG. 5D, the tip of the capillary is moved above the second pad 542 in order to align the wire with the second device bond pad. The capillary is then lowered to bring the wire in contact with second pad 542, bending the wire along the capillary curve with the front radius 312. The wire is clamped between the flat capillary material 313 in the horizontal plane and second pad 542, which is also in the horizontal plane. Pressure is applied to the capillary and the wire so that the wire is somewhat flattened. Simultaneously, ultrasonic energy is applied to the bent wire portion for a period of time to further enhance interdiffusion of the wire metal and the metal of the second pad. As a result, a stitch bond 560 is created between the wire and the second pad; the heel 412 of stitch bond 560 has been determined by the front radius 312 of the capillary.

In FIG. 5E, the capillary is lifted from stitch bond 560 until a certain length of wire is freed up to engage a wire tear mechanism, such as a clamp-tear or a table-tear method, to form a new tail 522 (see FIG. 5F). The stitch bonding cycle can start again as shown in FIG. 5A.

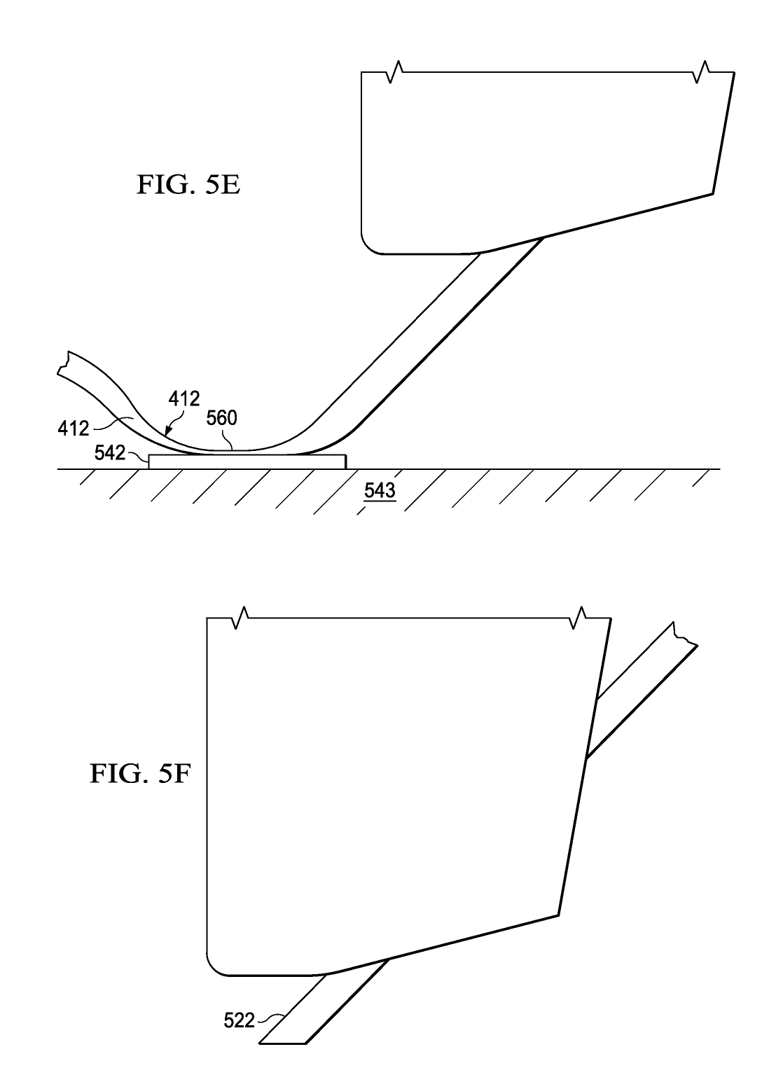

FIGS. 6A and 6B illustrate an exemplary embodiment of the invention for use in the fabrication of semiconductor devices. FIG. 6A shows a scanning electron microscope photograph (magnification 600×) of the tip of a capillary made of an inert material such as tungsten carbide. The cylindrical bore has dimensions suitable for round wires with a diameter in the range from about 15 μm to 35 μm; the wires for semiconductor devices may be made of copper, gold, aluminum, or alloys of these metals. The capillary bore widens to an elongated mouth at the end of tube. The tube end includes planar surface portions as well as portions with curved or rounded features. Specifically, FIG. 6A shows the planar capillary surface 610; the planar surface 613, which is in a plane at right angle with surface 610; and planar surface 615, which is in a plane at an acute angle with the plane of surface 613. The transition of surface 613 and surface 610 has a rounded edge, called the first curve and characterized by the front radius 612, and the transition of surface 613 and surface 615 has a rounded transition, called the second curve and characterized by the back radius 616.

FIG. 6A and, in a magnified view, FIG. 6B illustrate the addition of a concave recess 670 into the capillary material of the first curve. The purpose of the recess is the formation of a metal bulge in the heel of a stitch bond in order to strengthen the heel as the weakest link of a bond, and thus of the overall strength of the bond as apparent in bond pull tests. The recess depicted in the figures is shaped as a bowl or dish with a depth of about 3 μm and a diameter between about 20 μm and 40 μm. Alternative recesses may have greater or smaller diameters and depths, and may have other shapes, for example an indent, a chamfer, a groove, a wedge, or a flute. Depth and diameter of a recess are generally comparable to the diameter of the wire and may thus be greater of smaller than the ones shown in FIG. 6A and 6B. The most effective shape and depth of a recess is a function of the metals of the wire and the substrate, and of the bonding conditions including temperature, time, pressure and ultrasonic energy.

A similar recess, although not shown in FIGS. 6A and 6B, may be formed into the capillary material at the transition from the planar material 613 to the planar material 615. As stated in conjunction with FIG. 3A, this transition is curved into the elongated mouth of the capillary bore and is characterized by the back radius 616.

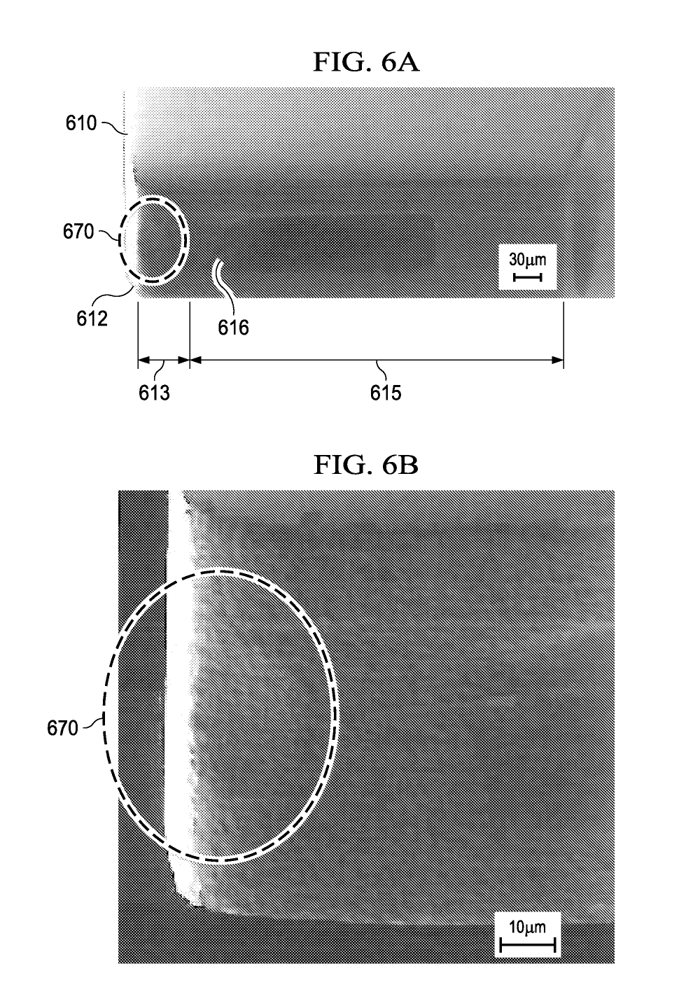

With a recess in the capillary material of the front radius region and a recess in the capillary material of the back radius region, the simple test structure depicted in FIG. 7 investigates strength and eventual break of stitch bond heels as influenced by additional metal bulges. The bulge formed in the vertex of the heel influenced by the front radius region 712 of a capillary tip is designated 712a, and the bulge formed in the vertex of the heel influenced by the back radius region 716 is designated 716a. The stitch bonds and bulges may be formed under various bonding pressures, ultrasonic energies, and temperatures, and to pads (743, 740) of various metals.

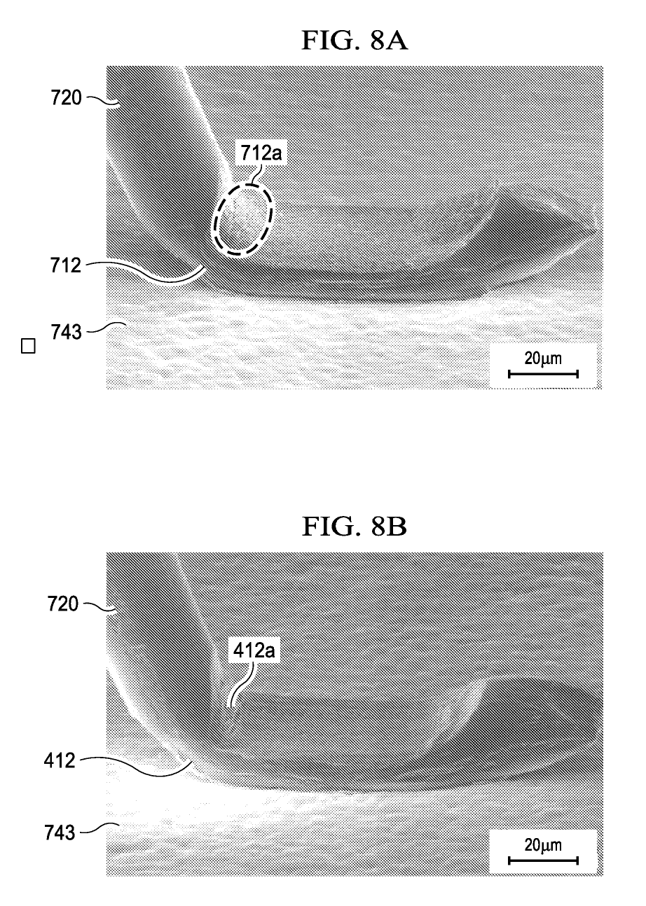

Using a capillary with an additional recess as shown in FIGS. 6A and 6B for a bonding process as illustrated in FIG. 5D results in a stitch bond as depicted in FIG. 8A (magnification 1800×). The metal wire 720 (in this example, gold) is flattened on a substrate 843 (in this example, gold-clad copper), while the heel 712 of the stitch bond is fortified by a metal bulge 712a in the vertex of the heel. This bulge has been formed from the softened wire metal during the time of elevated temperature, pressure and ultrasonic energy of the bonding process using the front radius 612 enhanced by recess 670 of the capillary.

The impact of structure and configuration of the vertex with the additional bulge 712a becomes evident, when one compares this vertex of the stitch bond heel 712 in FIG. 8A with the vertex 412a of the stitch bond heel 412 in FIG. 8B. The stitch bond in FIG. 8B was obtained under identical conditions (wire metal gold, substrate metal gold-clad copper, temperature, pressure, ultrasonic energy) to the conditions for FIG. 8A, except for the additional recess 670 in the capillary tip region of the front radius. Comparing the vertexes of the wire bendings in the heels of the stitch bonds of FIG. 8A and FIG. 8B, one can recognize the additional physical bulk created by the concave recess added to the tip of the capillary used for the stitch bonding.

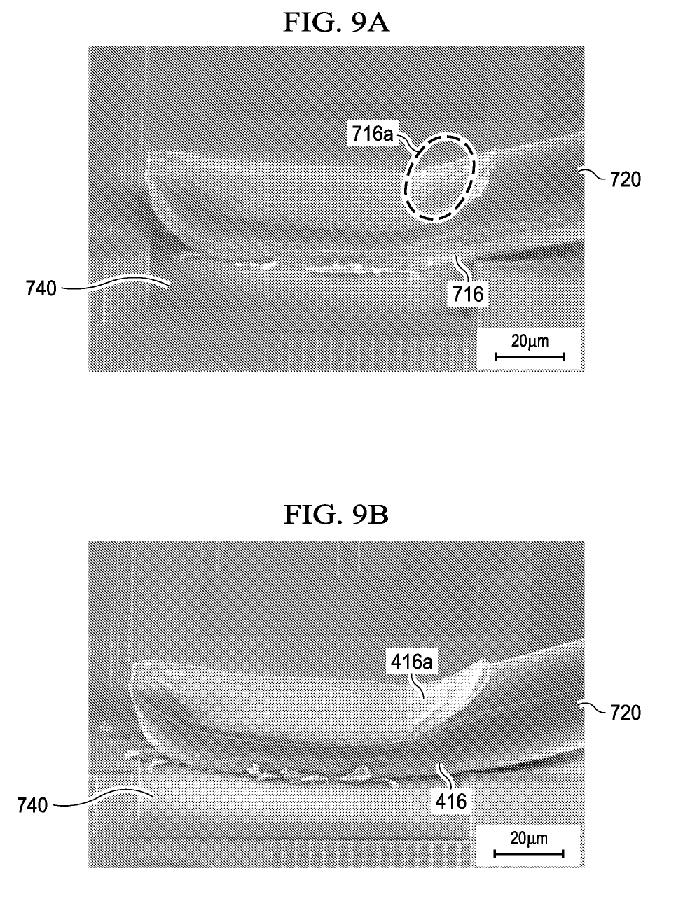

In an analogous fashion, a capillary with an additional recess in the capillary material of the back radius of the capillary tip can be used in a bonding process as illustrated in FIG. 5C. As an example, the recess may be shaped as a concave bowl with a depth between 3 μm to 5 μm in the region of the back radius of the capillary tip. Using a wire 720 of gold and a semiconductor bonding pad 740 of gold-clad copper results in a stitch bond as depicted in FIG. 9A (magnification 1800×). The metal wire 720 is flattened on the chip bonding pad 740, while the heel 716 of the stitch bond is fortified by metal bulge 716a in the vertex of the heel. This bulge has been formed from the wire metal softened during the time of elevated temperature, pressure and ultrasonic energy of the bonding process using the recess-enhanced back radius of the capillary.

The impact of structure and configuration of the vertex with the additional bulge 716a becomes evident, when one compares this vertex of the stitch bond heel 716 in FIG. 9A with the vertex 416a of the stitch bond heel 416 in FIG. 9B. The stitch bond in FIG. 9B was obtained under identical conditions (wire metal gold, substrate metal gold-clad copper, temperature, pressure, ultrasonic energy) to the conditions for FIG. 9A, except for the additional recess in the capillary tip region of the back radius. Comparing the vertexes of the wire bendings in the heels of the stitch bonds of FIG. 9A and FIG. 9B, one can recognize the additional physical bulk created by the concave recess added to the tip of the capillary (in the area of the front radius) used for the stitch bonding.

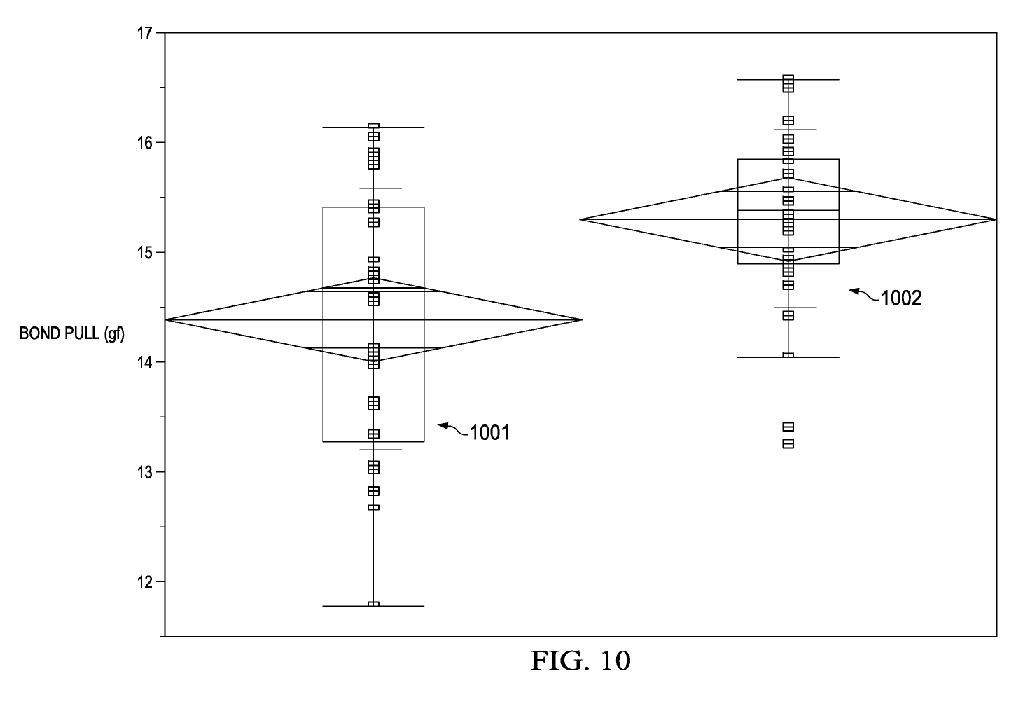

That the strengthening of the bond heels improves the robustness of the stitch bonds is corroborated by the data plotted in FIG. 10. Size and statistical distribution of the bond pull strength data, expressed in gram-force, is plotted for stitch bonds without (data 1001) and with (data 1002) additional metal bulges depicted in FIGS. 8A and 9A in the vertices of their stitch bond heels. As FIG. 10 shows, the average bond pull strength (data 1002) of the fortified stitch bonds increased by 6% compared to the pull strength of standard bonds without fortification by metal bulges.

Another embodiment of the invention is a method for fabricating a device having wire ball and stitch bonds. The method starts with providing a device having metallic bond pads; the device is assembled on a substrate with metallic contact pads, such as a leadframe.

In the next step, a lengthy tube is provided, which has inside a capillary comprising a cylindrical bore of small diameter; the capillary is loaded with a metal bonding wire with the tail portion of the wire protruding from the capillary mouth. At the tube end with the capillary mouth, the tube material is contoured by intersecting first and second planes; the first plane is at right angle to the tube length and the second plane is at an acute angle, the intersection is touching the mouth of the capillary. At the intersection, the tube material is forming a first curve from the first plane into the capillary mouth, and at the edge of the first plane and the tube surface, the material is forming a second curve. A concave recess such as an indent or a chamfer is positioned in the material of the first curve, characterized by the front radius.

In the next process step, device and substrate are heated to a temperature suitable for accelerating metal interdiffusion and the formation of intermetallic compounds. The tube is then moved to align the protruding wire tail with a first device bond pad. Thermal energy is applied to transform the protruding wire tail portion into a free air ball.

The tube is lowered to bring the free air ball into contact with the first bond pad. Pressure and ultrasonic energy are applied to the ball for a period of time to flatten the ball between wire and the first pad, and to create intermetallic compounds of the metals of the wire and the pad.

The tube is then lifted again and moved to provide additional wire length for spanning an arch to a second bond pad, in this example the lead of a leadframe. After spanning the arch, the tube is lowered to bring the wire in contact with the second metal pad.

In this process step, the wire is bent along the second curve to be clamped between the tube material oriented in the first plane and the second bond pad. Pressure and ultrasonic energy are then applied to the bent wire for a period of time in order to interdiffuse the metals of the wire and the second pad, creating a stitch bond between the wire and the second pad. Due to the concave recess in the capillary material characterized by the front radius, a metal bulge is created near the center of the wire bending, fortifying the bent wire in the vertex of the bond heel. Finally, the tube is lifted again to engage a tear technique for breaking the wire, creating a new wire tail protruding from the capillary mouth.

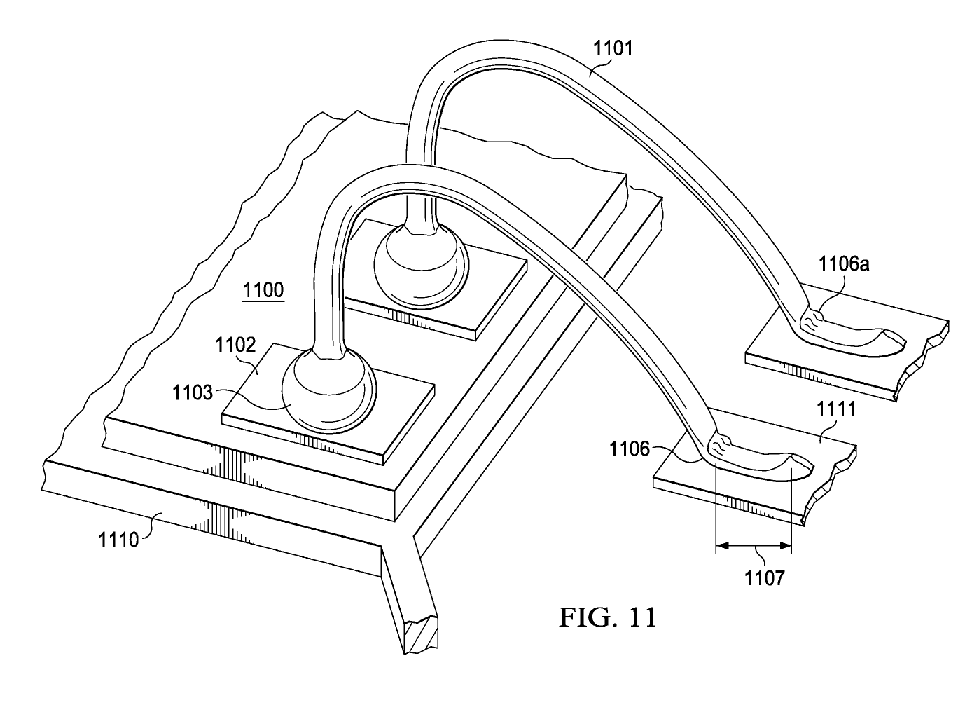

FIG. 11 shows a portion of an exemplary semiconductor device with wire bonds including stitch bonds. A semiconductor chip 1100 is assembled on a substrate 1110; the chip has bond pads 1102 and the substrate has contact pads 1111. Wires 1101 form arches to connect electrically the chip and the substrate. The wires form first bonds on the chip bond pads, which are ball bonds in the example of FIG. 11, and second bonds on the substrate contact pads, which are stitch bonds with a flattened portion 1107. As FIG. 11 further shows, the stitch bonds have bent wires with a transition 1106 from the round wire portion to the flat wire portion 1107, and metal bulges 1106a near the vertex of the bending. The impact of these bulges 1106a on improving the strength of the stitch bonds has been discussed in FIG. 10.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, depth and diameter of the recess may vary as a function of the wire metal, the thickness of the wire, the angle of the wire bending at the at the stitch bond, and the length of time temperature, pressure, and ultrasonic energy dispensed.

It is therefore intended that the appended claims encompass any such modifications or embodiments.

1. An apparatus for use in wire bonders comprising:
a tube of a length having a surface and walls made of a material and surrounding a capillary bore, the material at the capillary mouth contoured by intersecting first and second planes, wherein the first plane is at right angle to the tube length and the second plane at an acute angle, the intersection at the mouth of the capillary bore;
at the edge of the first plane and the tube surface, the material forming a first curved surface, and at the intersection of the first and second planes, the material forming a second curved surface; and
at least one concave recess in the material of the first and the second curved surfaces.

2. The apparatus of claim 1 wherein the material of the tube is selected from a group including tungsten carbide, corundum, and sapphire.

3. The apparatus of claim 1 wherein the concave recesses are positioned in the center portions of the curved surfaces.

4. The apparatus of claim 1 wherein the concave recesses have a contour selected from a group including concave bowl, dish, indent, chamfer, groove, wedge, and flute.

5. The apparatus of claim 1 wherein the first curved surface is characterized by a front radius and the second curved surface is characterized by a back radius.

6. A method for fabricating a device having wire bonds comprising:
providing a device having metallic bond pads, the device assembled on a substrate;
providing a tube having a capillary loaded with a metal bonding wire, at the tube end with the capillary mouth the tube material contoured by intersecting first and second planes, wherein the first plane is at right angle to the tube length and the second plane at an acute angle, the intersection touching the mouth of the capillary; at the edge of the first plane and the tube surface, the material forming a first curve; at the intersection, the material forming a second curve from the first plane into the capillary mouth; at the edge of the first plane and the tube surface, the material forming a second curve; a concave recess in the material of the first and the second curves; the tail portion of the wire protruding from the capillary mouth;
heating device and substrate to a temperature accelerating metal interdiffusion;
moving the tube to align the protruding wire tail with a first device bond pad;
lowering the tube to bring the wire in contact with the first pad, bending the wire tail portion along the second curve and clamping the wire portion between the tube material in the first plane and the first pad;
applying pressure and ultrasonic energy onto the bent wire portion for a period of time to interdiffuse the metals of the wire and the first pad, creating a stitch bond between the wire and the first pad, and to form a metal bulge near the center of the wire bending, fortifying the wire in the vertex of the bending;
lifting and moving the tube to provide additional wire length for spanning an arch to a second bond pad;
lowering the tube to bring the wire in contact with the second pad, bending the wire along the first curve and clamping the wire between the tube material in the first plane and the second pad;
applying pressure and ultrasonic energy onto the bent wire for a period of time to interdiffuse the metals of the wire and the second pad, creating a stitch bond between the wire and the second pad, and to form a metal bulge near the center of the wire bending, fortifying the wire in the vertex of the bending; and
lifting the tube to engage a tearing technique for breaking the wire.

7. The method of claim 6 wherein the first and the second curves have size and shape for forming wire angles at the heels of stitch bonds.

8. The method of claim 7 wherein the concave recesses have size and shape for forming metal bulges in the heels of stitch bonds.

9. The method of claim 8 wherein the concave recesses of are located to form metal bulges at the vertex of the heels.

10. A method for fabricating a device having wire bonds, comprising:
providing a device having metallic bond pads, the device assembled on a substrate;
providing a tube having a capillary loaded with a metal bonding wire, the tail portion of which protruding from the capillary mouth, at the tube end with the capillary mouth the tube material contoured by intersecting first and second planes, wherein the first plane is at right angle to the tube length and the second plane at an acute angle, the intersection touching the mouth of the capillary; at the edge of the first plane and the tube surface, the material forming a first curve; at the intersection, the material forming a second curve from the first plane into the capillary mouth; a concave recess in the material of the first curve;
heating device and substrate to a temperature for forming intermetallic compounds and metal interdiffusion;
moving the tube to align the protruding wire tail with a first device bond pad;
applying thermal energy to transform the wire tail portion into a free air ball;
lowering the tube to bring the free air ball into contact with the first pad and applying pressure and ultrasonic energy onto the ball for a period of time to create intermetallic compounds of the metals of the wire and the first pad, creating a flattened ball bond between the wire and the first pad;
lifting and moving the tube to provide additional wire length for spanning an arch to a second bond pad;
lowering the tube to bring the wire in contact with the second pad, bending the wire along the first curve and clamping the wire between the tube material in the first plane and the second pad;
applying pressure and ultrasonic energy onto the bent wire for a period of time to interdiffuse the metals of the wire and the second pad for creating a stitch bond between the wire and the second pad, and to form a metal bulge near the center of the wire bending, fortifying the wire in the vertex of the bending; and
lifting the tube to engage a tear technique to break the wire.

11. The method of claim 10 wherein the first and the second curves have size and shape for forming wire angles at the heels of stitch bonds.

12. The method of claim 10 wherein the concave recesses have size and shape for forming metal bulges in the heels of stitch bonds.

13. The method of claim 12 wherein the concave recesses of are located to form metal bulges near or at the vertex of the heels.

14. A device comprising:
a semiconductor chip assembled on a substrate, the chip having bond pads and the substrate having contact pads; and
wires forming arches to connect electrically the chip and the substrate, the wires forming first bonds on the chip bond pads and second bonds on the substrate contact pads,
the bonds including stitch bonds having bent wires with metal bulges near the vertex of the bending.

15. The device of claim 14 wherein the first bonds are ball bonds and the second bonds are stitch bonds.

16. The device of claim 14 wherein the first bonds and the second bonds are stitch bonds.
